(19) United States
(12) Patent Application Publication
(10) Pub. No.: US 2009/0231808 A1
(43) Pub. Date: Sep. 17, 2009

(54) Enclosure For Flat Panel Monitors

(76) Inventor: Robert Daniel Burgner, Port St. Joe, FL (US)

Correspondence Address: TROUTMAN SANDERS LLP;BANK OF AMERICA PLAZA, 600 PEACHTREE STREET, N.E., SUITE 5200, ATLANTA, GA, 30308-2216, US

(21) Appl. No.: 12/401,947

(22) Filed: Mar. 11, 2009

Related U.S. Application Data
(60) Provisional application No. 61/035,596, filed on Mar. 11, 2008.

(51) Int. Cl. H05K 7/20; H05K 5/00; B23P 17/00

(52) U.S. Cl. 361/695; 361/679.01; 361/690; 29/592.1

(57) ABSTRACT

A device generally intended to be used for providing an enclosure for a wall-mounted flat panel monitor. The device comprises an enclosure with a front face angled to match the mounting angle of the flat panel monitor. The device can further comprise a ventilation port to provide circulation around the flat panel monitor. The device can further comprise a cooling fan to improve airflow around the flat panel monitor. The device can be constructed from wood, plastic, metal, other suitable materials, or a combination of suitable materials. The device can provide a surface for attaching a flat panel monitor mounting bracket or can enable the mounting bracket to be attached to the adjoining wall.

### CROSS REFERENCE TO RELATED APPLICATION

This application claims benefit under 35 U.S.C. §119(e) of U.S. Provisional Patent Application Ser. No. 61/035,596 filed 11 Mar. 2008 which application is hereby incorporated fully by reference.

### BACKGROUND OF THE INVENTION

1. Field of the Invention

The present invention relates generally to a device for enclosing flat panel monitors, and in particular, to a frame for enclosing a wall-mounted flat panel monitor, the wiring, and equipment associated therewith.

2. Description of Related Art

Flat panel monitors of various types have become common pace in the American household, and indeed, around the world. The technology associated with flat panel monitors has improved at a rapid pace, increasing both resolution and response time, while lowering production costs. This has enabled flat panel monitors to take a primary role for many uses including, among other things, televisions, computer monitors, and cash register displays.

Two main types of flat panel monitors have become most commercially viable: the plasma display panel (“PDP”) and the liquid crystal display (“LCD”). Both technologies provide high resolution pictures and can be packaged in commercially advantageous ways.

A PDP is a type of flat panel display most commonly associated with large TV displays (greater than 37 inches.) Many tiny cells, sandwiched between two panels of glass, hold an inert mixture of noble gases. The gas in the cells is electrically turned into plasma which then excites phosphors to emit light. PDPs have excellent contrast ratios, i.e. that ratio between the light emitted when a pixel displays white and when it is off, or black. PDPs also have a wide viewing angle and fast response and refresh rates. Response and refresh rates become particularly important as screen sizes increase and scene changes become correspondingly more obvious.

LCDs, on the other hand, use liquid crystals sandwiched between two pieces of glass and a backlighting system. The amount of light let through by a particular crystal is dependent on the amount of voltage that is applied to the crystal. LCDs tend to have higher native resolution than PDPs and typically consume up to 30% less power than a comparable PDP. Also, because LCDs generally do not have a large, protective piece of glass on the screen, they tend to be lighter, making them easier to move and/or wall-mount.

On the other hand, LCDs tend to have slower response and refresh rates. This can lead to ghosting and other image problems when displaying fast action scenes. LCDs also tend to have lower contrast ratios due to bleed through from the back lighting when a pixel is turned off or black. Finally, due in part to the polarizing screens necessary for proper function of an LCD, they tend to have narrower viewing angles than do PDPs.

Both LCDs and PDPs (“monitors”) are sufficiently thin and light, however, to enable them to be mounted on a wall. This can obviate the need for a table, desk, or entertainment center on which to place the monitor. Many homes, offices, and businesses have monitors mounted on the wall where, conventionally, a picture might have hung. In homes, for example, they can be mounted on the wall or over the fireplace mantel. Bars and taverns often mount monitors high on the wall to maximize viewing and also to prevent patrons from changing channels, volume levels, or other settings. Monitors are often mounted in businesses to entertain waiting customers.

Mounting a monitor on the wall can save space, provide a better viewing angle, and can enable a monitor to be integrated into home décor more easily. Wall mounts, however, create a separate set of challenges. For instance, most wall mounts consist of one or more metal brackets to attach the monitor to the studs, or other structure, inside the wall. These metal brackets are often painted black and can be difficult to coordinate with surrounding decorative elements.

Monitors, especially those used as part of a home entertainment system, can also require multiple connections including but not limited to, power cords, audio cables, speaker wires, HDMI cables, and component video cables. While the monitor may be attractive, therefore, the multiple cables and cords generally are not. Thus, the separate problem of what to do with the unsightly cables and cords presents itself.

Conventionally, one solution has been to run the cables in the wall from the source to the monitor. This can require removing portions of the wall and/or sheathing, drilling holes in framing, and can be cost and time prohibitive. A second solution is to cable tie all the wires and cables together and place them in a conduit, or other accessory, that is then surface mounted on the wall. This can tidy the appearance of the installation, but often nonetheless looks temporary and/or unprofessional. Finally, picture type frames exist that surround the monitor and tend to help blend the monitor into the surrounding décor. But this does nothing to contain and/or hide the cables associated with the monitor. Picture frame type mounts are also generally suitable only for monitors mounted parallel to the wall.

What is needed, therefore, is a device that comprises a decorative frame that can be mounted behind and/or around a wall-mounted monitor to improve its aesthetics, yet provide convenient storage for a plurality of cables and other accessories associated with a monitor. The device should be easily wall mountable and cost effective. The device should provide ventilation for the monitor and associated equipment. It is to such a device that embodiments of the present invention are directed.

### BRIEF SUMMARY OF THE INVENTION

Briefly described, the present invention is a device for enclosing a flat panel monitor in a decorative and functional manner. In some embodiments, the present invention comprises a device for enclosing a wall-mounted flat panel monitor comprising a top panel with a proximate end and a distal end and disposed in a substantially horizontal manner, a first side panel detachably coupled to the proximate end of the top panel in a substantially vertical manner and comprising a leading edge disposed at substantially the same angle as a mounting angle for an enclosed flat panel monitor, a second side panel detachably coupled to the distal end of the top panel in a substantially vertical manner and comprising a leading edge disposed at substantially the same angle as a mounting angle for an enclosed flat panel monitor, one or more frame elements detachably coupled to a front face of the top panel and the first and second side panels for surrounding a flat panel monitor, and defining an air gap therebetween.

In some embodiments, the present invention can further comprise a ventilation port to enable air flow around an enclosed flat panel monitor. In other embodiments, the present invention can comprise a cooling fan to increase air flow around a flat panel monitor. In still other embodiments, the device can comprise a bottom panel detachably coupled to a bottom edge of the first and second side panels in a substantially horizontal manner, and a frame element detachably coupled to a front face of the bottom panel for surrounding a flat panel monitor, and defining an air gap therebetween.

In some embodiments, the device can further comprise one or more mounting brackets disposed on a rear edge of one or more of the top panel or the side panels for attaching the device on a wall. In still other embodiments, the device can further comprise a rear panel detachably coupled to a rear edge of one or more of the top panel, side panels, and bottom panel. In an exemplary embodiment the rear panel can further comprise a rigid material for mounting a mounting bracket for a flat panel monitor thereon. In other embodiments, the rear panel can further comprise one or more mounting holes for mounting the device on a wall. In some embodiments, the device can further comprise one or more mounting brackets disposed on a rear edge of one or more of the top panel, side panels, and bottom panel for attaching the device on a wall.

In some embodiments, the present invention can comprise a device for enclosing a wall-mounted flat panel monitor comprising a top panel with a proximate end and a distal end and disposed in a substantially horizontal manner and further comprising a ventilation port, a first side panel with a proximate end and a distal end, the proximate end detachably coupled to the proximate end of the top panel in a substantially vertical manner and comprising a leading edge disposed at substantially the same angle as a mounting angle for an enclosed flat panel monitor, a second side panel with a proximate end and a distal end, the proximate end detachably coupled to the distal end of the top panel in a substantially vertical manner and comprising a leading edge disposed at substantially the same angle as a mounting angle for an enclosed flat panel monitor, a bottom panel detachably coupled to the distal end of the first side panel and the second side panel in a substantially horizontal manner, and one or more frame elements detachably coupled to a front face of the top panel, first and second side panels, and bottom panel for surrounding a flat panel monitor and defining an air gap therebetween.

In other embodiments, the device can further comprise a cooling fan detachably coupled inside the top panel and below the ventilation port for increasing airflow around the flat panel monitor. In some embodiments, the leading edge of the first side panel and the second side panel can be disposed between approximately −15 degrees and +15 degrees. In still other embodiments, the device can comprise a rear panel detachably coupled to a rear edge of one or more of the top panel, side panels, and bottom panel. In an exemplary embodiment, the rear panel can further comprise a rigid material for mounting a mounting bracket for a flat panel monitor thereon.

Embodiments of the present invention can comprise a method for manufacturing a device for enclosing a wall-mounted flat panel monitor comprising providing a top panel with a proximate end and a distal end, providing a first side panel, comprising a proximate end and a distal end, and comprising a first edge disposed at substantially the same angle as a mounting angle for an enclosed flat panel monitor, providing a second side panel comprising a proximate end and a distal end, and comprising a first edge disposed at substantially the same angle as a mounting angle for an enclosed flat panel monitor, providing a bottom panel, providing one or more frame elements, creating one or more ventilation ports in the top panel to provide airflow around a flat panel monitor, attaching the proximate end of the first side panel to the proximate end of the top panel in a substantially perpendicular manner, attaching the proximate end of the second side panel to the distal end of the top panel in a substantially perpendicular manner, attaching the bottom panel to the distal end of the first side panel and second side panel, and attaching the frame elements to a front edge of the top and bottom panels and the first edge of the side panels for surrounding a flat panel monitor and defining an air gap therebetween.

In some embodiments, the method can further comprise providing one or more cooling fans, and attaching the one or more cooling fans to a bottom side of the top panel such that they are substantially aligned with the one or more ventilations ports therein. In other embodiments, the top panel, side panels, and bottom panel can comprise a single piece that is integrally formed. In still other embodiments, the present invention can comprise providing a storage means for cords and accessories associated with an enclosed flat panel monitor and associated equipment. In yet other embodiments, the present invention can comprise providing a rear panel, and attaching the rear panel to a rear edge of one or more of the top panel, side panels, and bottom panel. Finally, in some embodiments, the rear panel can comprise a rigid material for mounting a mounting bracket for a flat panel monitor thereon.

### BRIEF DESCRIPTION OF THE FIGURES

FIG. 1A illustrates a perspective, front view of a device for providing an enclosure for flat panel monitors in accordance with some embodiments of the present invention.

FIG. 1B illustrates a perspective, front view of a device for providing an enclosure for flat panel monitors in accordance with some embodiments of the present invention.

FIG. 2A illustrates a front view of a device for providing an enclosure for flat panel monitors in accordance with some embodiments of the present invention.

FIG. 2B illustrates a front view of a device for providing an enclosure for flat panel monitors in accordance with some embodiments of the present invention.

FIG. 2C illustrates a front view of a device for providing an enclosure for flat panel monitors in accordance with some embodiments of the present invention.

FIG. 3 illustrates a side view of a device for providing an enclosure for flat panel monitors in accordance with some embodiments of the present invention.

FIG. 4A illustrates a top view of a device for providing an enclosure for flat panel monitors in accordance with some embodiments of the present invention.

FIG. 4B illustrates a top view of a device for providing an enclosure for flat panel monitors in accordance with some embodiments of the present invention.

FIG. 5A illustrates a side view of a device for providing an enclosure for flat panel monitors in accordance with some embodiments of the present invention.

FIG. 5B illustrates a detailed, side view of a device for providing an enclosure for flat panel monitors in accordance with some embodiments of the present invention.

FIG. 6 illustrates a side view of a device for providing an enclosure for flat panel monitors in accordance with some embodiments of the present invention.

FIG. 7 illustrates a perspective, rear view of a device for providing an enclosure for flat panel monitors in accordance with some embodiments of the present invention.

FIG. 8 illustrates a perspective, rear view of a device for providing an enclosure for flat panel monitors in accordance with some embodiments of the present invention.

### DETAILED DESCRIPTION OF PREFERRED EMBODIMENT

To facilitate an understanding of the principles and features of embodiments of the invention, they are explained hereinafter with reference to implementations in illustrative embodiments. Embodiments of the invention are described in the context of being a device and method for providing an enclosure for flat panel monitors and in particular, to providing a decorative enclosure for flat panel monitors and the cables and accessories associated therewith.

The material described hereinafter as making up the various elements of the present invention are intended to be illustrative and not restrictive. Many suitable materials that would perform the same or a similar function as the materials described herein are intended to be embraced within the scope of the invention. Such other materials not described herein can include, but are not limited to, materials that are developed after the time of the development of the invention, for example.

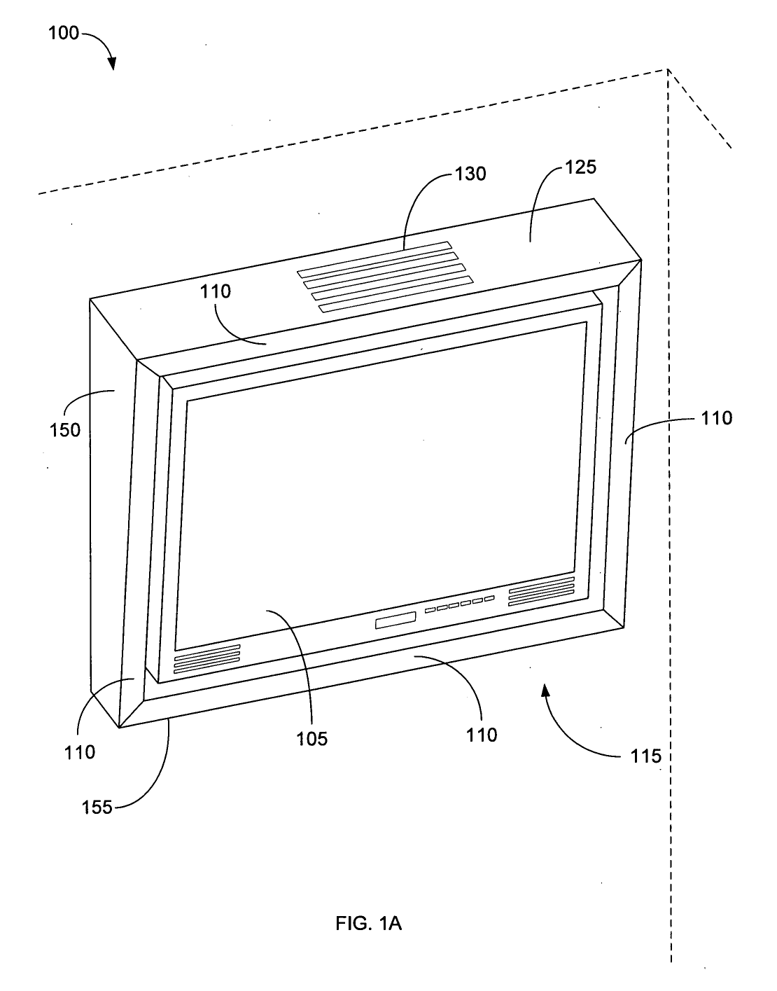

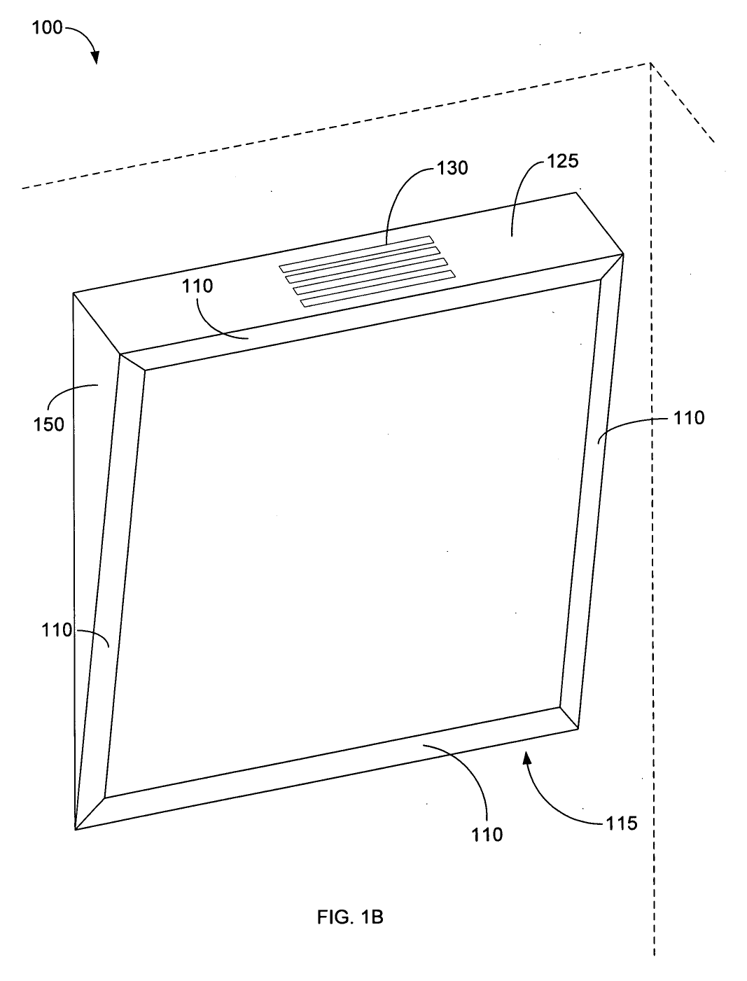

Referring now in detail to the drawings, wherein like reference numerals represent like parts throughout the several views, the present invention of FIG. 1A is a device 100 that provides an enclosure for flat panel monitors. The device 100 can be used in conjunction with, for example and not limitation, flat panel televisions, computer monitors, and digital picture frames.

In some embodiments, the device can comprise four frame elements 110. These elements 110 can comprise mitered trim pieces similar to those found on a picture frame. This can enable the monitor 105 to be framed in a decorative manner to suit the decor. For instance, a monitor 105 installed in one's living room can be framed with a design that matches other framed art in the room. A monitor 105 installed in a place of business, on the other hand, can be framed to match company design schemes and can also provide some protection for the monitor 105.

The device 100 can also comprise an enclosure 115. The enclosure 115 can further comprise two side panels 150. In some embodiments, such as when the monitor is mounted parallel to the wall, the side panels 150 can be substantially rectangular. In other embodiments, such as when the monitor is mounted in a non-parallel—or angled—position, the side panels 150 can be substantially trapezoidal. This can enable the front of the enclosure 115 to substantially match the mounting angle of the monitor 105. In still other embodiments, the side panels 150 can be substantially triangular. See, FIG. 1B.

In an exemplary embodiment, the enclosure 115 can further comprise a bottom panel 155 (not shown). This can enable the bottom of the enclosure 115 to house, for example and not limitation, power strips and cables. It is also contemplated, however, that the mounting angle of the monitor 105, storage requirements, or aesthetics, among other things, can dictate that side panels 150 be triangular, obviating the need for a bottom panel. See, FIG. 1B. In this embodiment, the enclosure 115 can further comprise a front panel 117.

In some embodiments, the enclosure 115 can further comprise a top panel 125. In order to provide ventilation for the equipment housed in the enclosure 115, the top panel can further comprise a ventilation port 130. The ventilation port 130 can be, for example and not limitation, a single opening, slots (shown), or a pattern of holes. In some embodiments, the ventilation port 130 can rely on natural thermodynamic flow to provide air flow through the enclosure 115. In some embodiments, the ventilation port 130 can further comprise a cooling fan, or other powered ventilation means, to promote air flow.

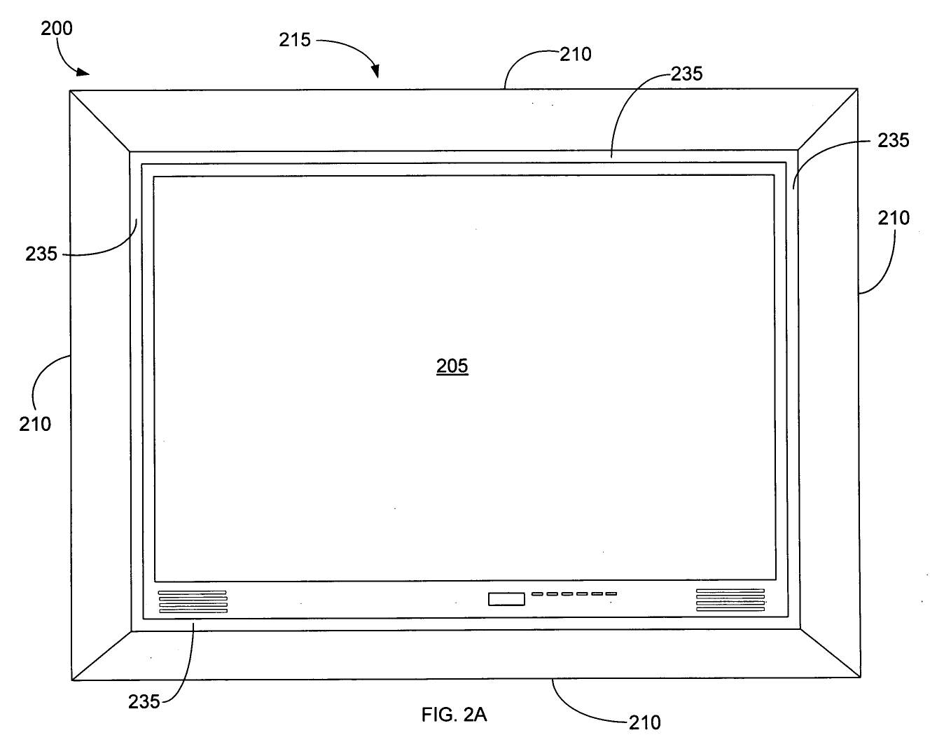

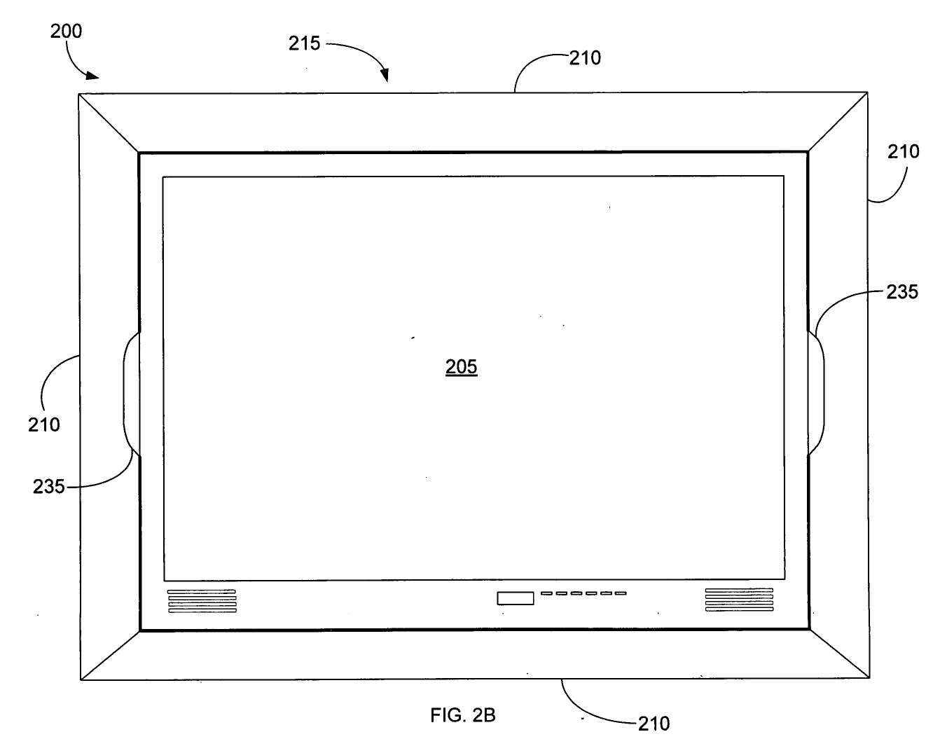

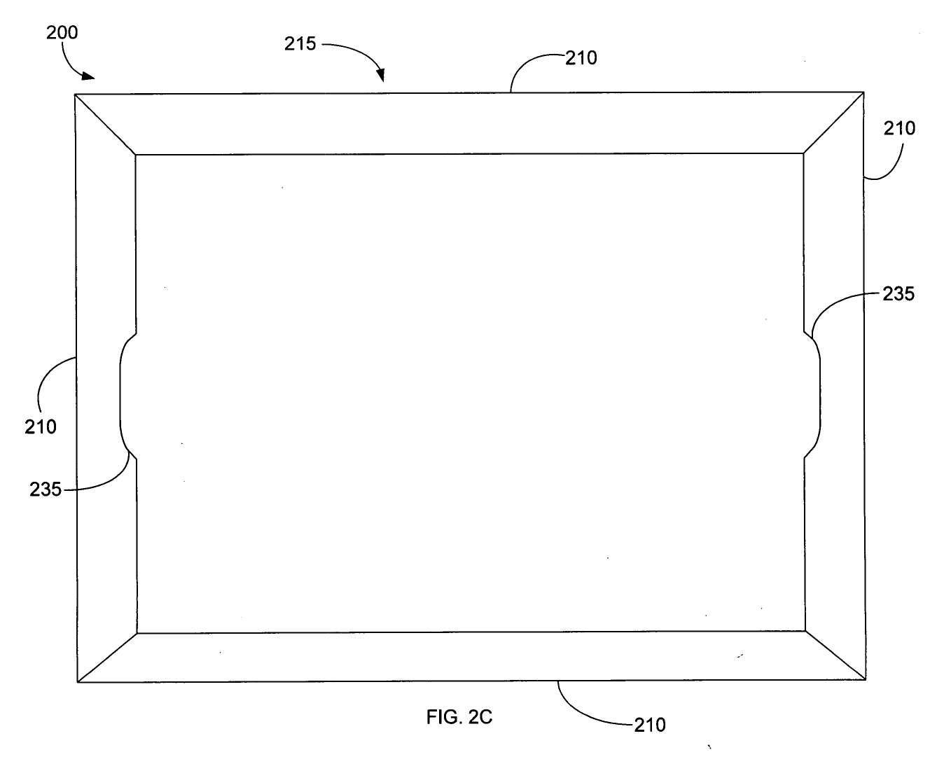

In some embodiments, as shown in FIG. 2A, the enclosure 215 can be sized such that an air gap 235 remains between the frame elements 210 and the monitor 205. This can enable air to pass between the frame elements 210 and the monitor 205 to provide cooling for the monitor 205 and other equipment located in the enclosure 215. In some embodiments, air flow can be provided by natural thermodynamic flow, i.e., warm air can rise and exit the ventilation port 130, thus pulling cooler air in through the air gaps 235. In other embodiments, forced air cooling can be provided by fans or other means.

In still other embodiments, shown in FIGS. 2B and 2C, the frame elements 210 can be disposed such that they are touching, or in very close proximity, to the monitor 205. In some embodiments, therefore, the air gaps 235 can comprise cut-outs in the frame elements 210 to enable cooling air to enter the enclosure 215. This can enable the enclosure 215 to be closely fit to the monitor 205 to improve, for example and not limitation, aesthetics, acoustics, or air management.

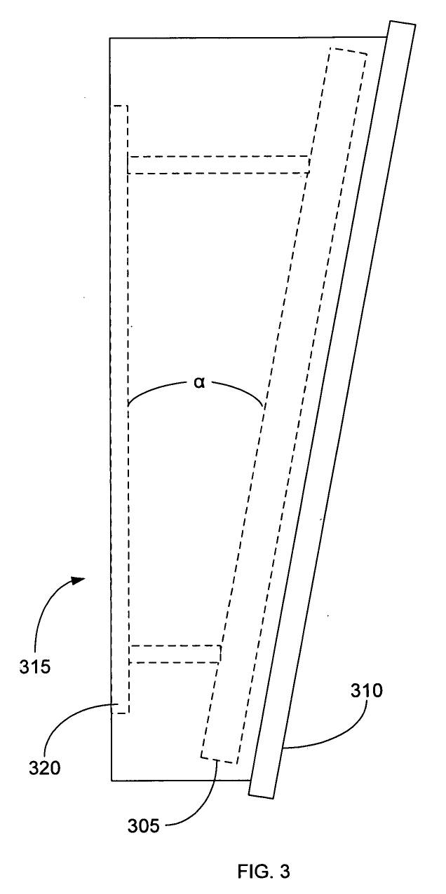

As shown in FIG. 3, the frame elements 310 can be mounted on the leading edge of the mounting enclosure 315. The mounting enclosure 315 can enclose the monitor 305 and the monitor mounting bracket 320. This can enable the rear and sides of the mounting bracket 320 and the monitor 305 to be hidden when installed. The mounting enclosure 315 can be constructed from, for example and not limitation, wood, engineered wood, metal, or plastic.

Monitors 305 are often mounted using angled brackets 320. This can enable the monitor 305 to be mounted higher than otherwise would be possible while still maintaining a desirable viewing angle. In some embodiments, the present invention can incorporate the included angle α of the monitor bracket to provide a flush enclosure for an angled monitor 305. Embodiments of the present invention can, therefore, be custom made to fit a desired mounting angle α or can be manufactured to correspond to a set mounting angle a of commercially available mounting brackets.

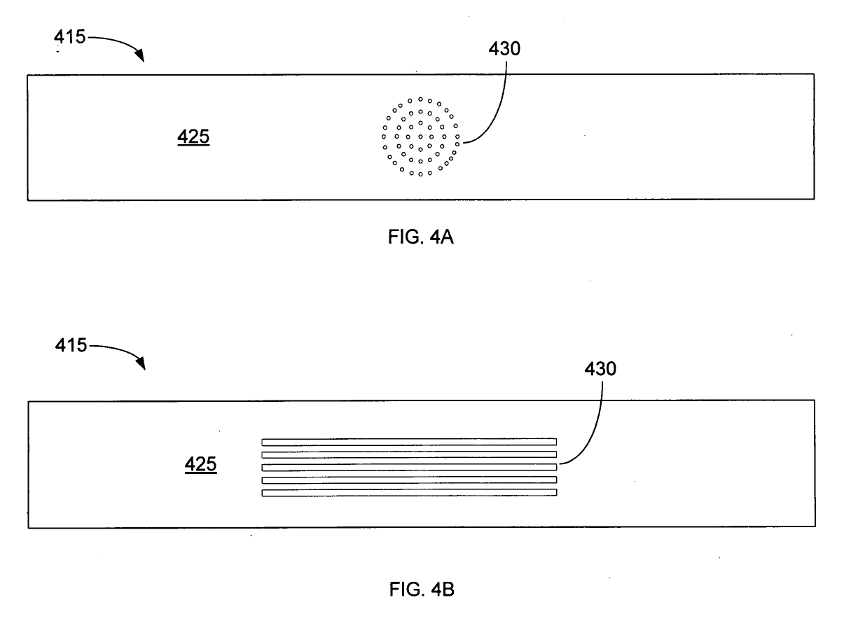

In still other embodiments, depicted in FIGS. 4A and 4B, the top 425 of the mounting enclosure 415 can comprise ventilation ports 430. In some embodiments, the ventilation ports 430 can be a pattern of circular holes (FIG. 4A) or rectangular slots (FIG. 4B), though other configurations are contemplated. The ventilation ports 430 can enable heat generated by the monitor to escape naturally from the top 425 of the mounting enclosure 415.

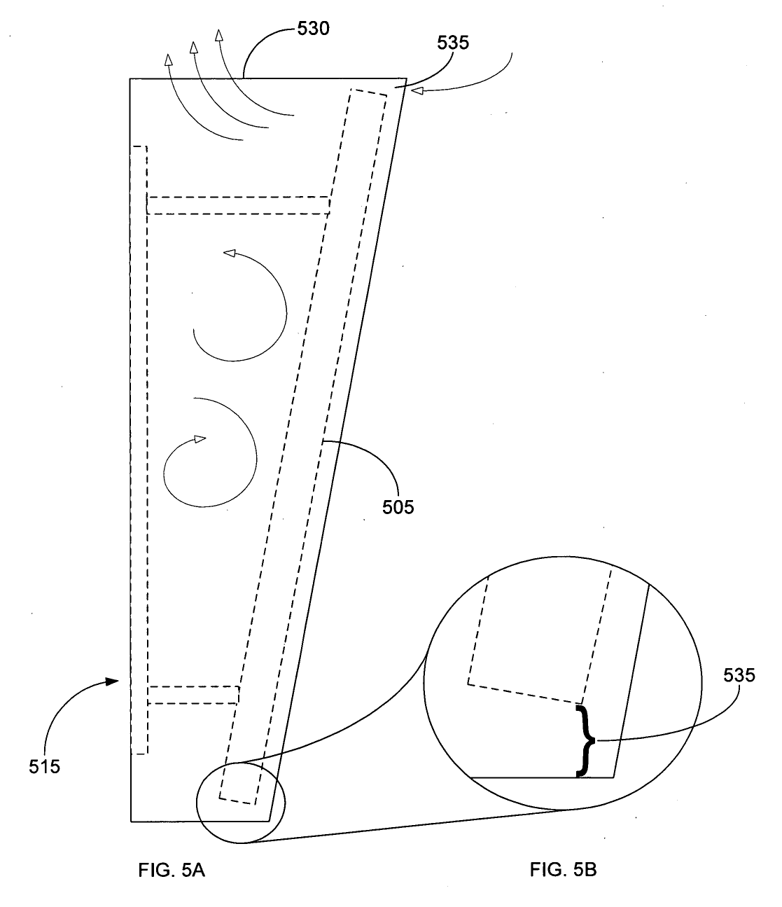

As shown in FIG. 5, in some embodiments, cooling can be provided for the monitor 505 using natural thermodynamic flow (indicated by the hollow tipped arrows.) In other words, as heat is created by the monitor 505 it naturally warms the air inside the enclosure 515. The warm air then rises and flows out of the ventilation ports 530 provided on the top of the enclosure 515. This, in turn, creates an area of low pressure behind the monitor 505 pulling cooler ambient air in around the monitor through the air gaps 535. This can provide passive cooling for the monitor 505 and enclosure 515 without the use of electric fans or other forced means. This, in turn, can reduce production costs, maintenance costs, and lower noise levels.

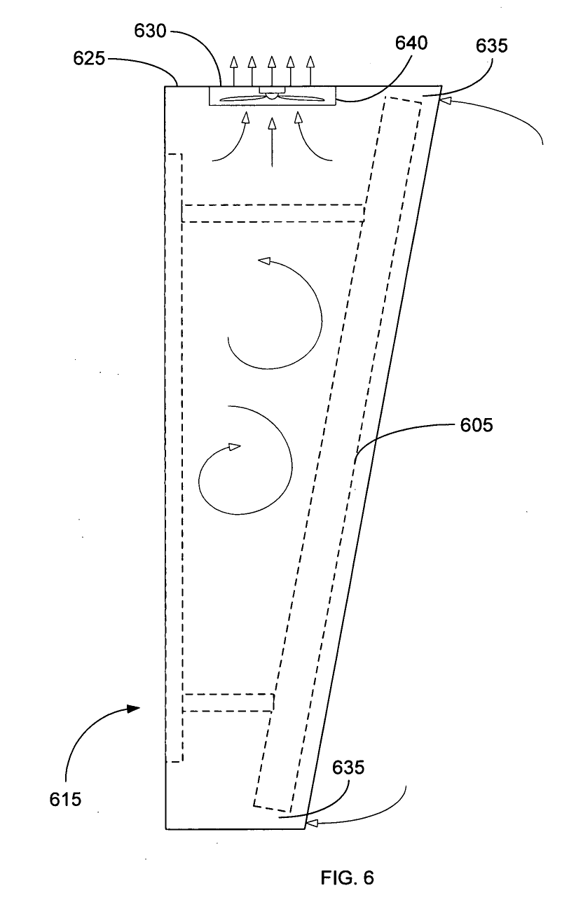

In some embodiments, it can be necessary to provide cooling fans, or other means, to maintain satisfactory operating temperatures inside the enclosure 615. See, FIG. 6. This can be necessary, for example, due to the high energy consumption and heat production inherent in large plasma televisions. In some embodiments, therefore, the mounting enclosure 615 can include a cooling fan 640. In an exemplary embodiment, the cooling fan 640 can be mounted inside the top 625 of the enclosure 615. This locates the fan 640 inside the enclosure 615, which can maintain a clean outward appearance for the enclosure 615.

In an exemplary embodiment, the cooling fan 640 can be mounted inside the enclosure 615 below the ventilation port 630. In the preferred embodiment, the fan can be mounted such that air is drawn from inside the enclosure 615 and expelled through the ventilation port 630. This can increase the flow (indicated by the hollow-tipped arrows) created by normal thermodynamics, described above, and increase the volume of cooling air drawn in through the air gaps 635 and expelled via the ventilation ports 630. Increased air flow can, in turn, maintain cooler temperatures inside the enclosure 615 and extend the life of the monitor 605 and associated components.

In an alternative embodiment, it can be necessary to use reverse flow, i.e. the fan can draw air into the enclosure via the ventilation port 630 and expel air through the air gaps 635. Reversing the airflow (against the natural thermodynamic flow) is not ideal but can be necessary, for example, when there is artwork, electronics, or other sensitive components mounted above the enclosure 615, or indeed anytime items are present that can react negatively to the airflow and heat exhausted from the enclosure 615. This reversed airflow can also be necessary to direct particulates such as dust, pet dander, and pet hair away from sensitive components.

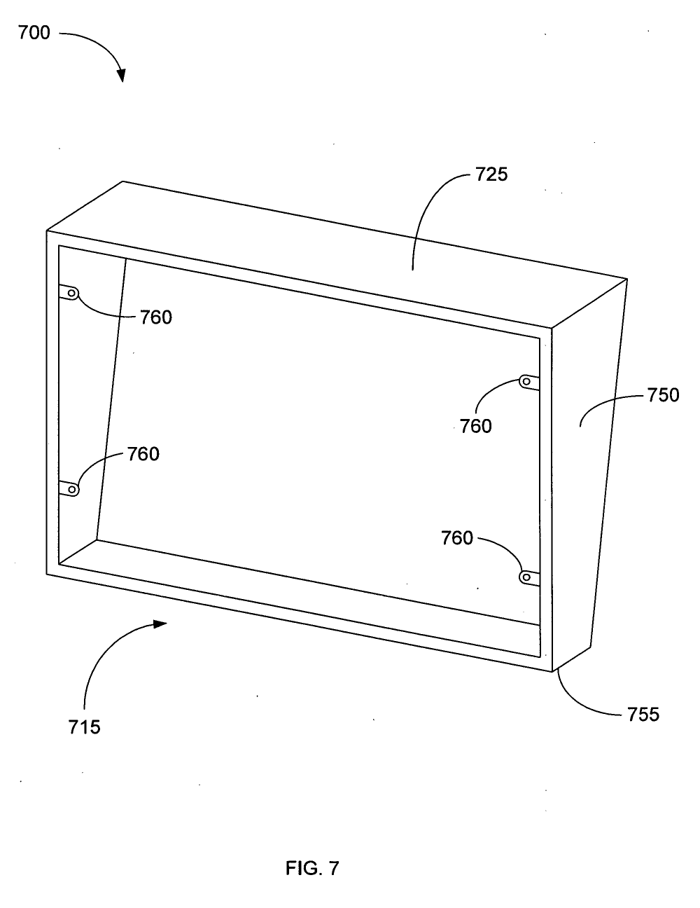

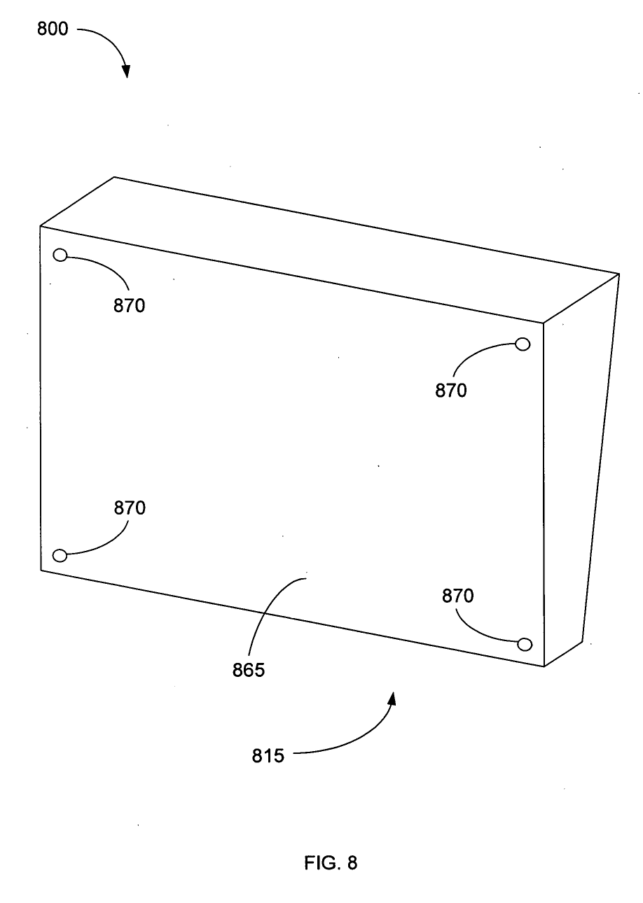

In some embodiments, shown in FIG. 7, the enclosure can be of a backless design. This can enable the device 700 to be mounted around existing monitor installations. In some embodiments, the enclosure 715 can further comprise mounting brackets 760. In some embodiments, the mounting can be mounted on the side panels 750, the top panel 725, the bottom panel 755, or any combination thereof. The mounting brackets 760 can enable the enclosure 715 to be secured to the wall using, for example and not limitation, screws, brads, nails, lags, or pins. In other contemplated embodiments, the enclosure 715 can be secured to the wall using a suitable adhesive.

In still other embodiments, the device 800 can further comprise a rear panel 865. The rear panel 865 can enclose the monitor and any associated cabling or hardware. In some embodiments, the rear panel 865 can further comprise mounting holes 870 to enable the enclosure 815 to be mounted to the wall. In some embodiments, the rear panel 865 can be structural in nature to enable the mounting bracket 320 to be attached directly to the enclosure 815. In other embodiments, the rear panel 865 can enable the mounting bracket 320 to be attached through the rear panel 865 and into the wall.

The device 100, 200 can comprise many different materials. For example and not limitation, the device 100, 200 can comprise wood. This can enable the device 100, 200 to be stained or painted, for example, to match the surrounding decor. In other embodiments, all or portions of the device 100, 200 can comprise, for example and not limitation, metal, plastic, or fiberglass. It is contemplated, however, that the device 100, 200 can comprise many suitably structural materials or combinations of materials.

For example, the enclosure 115 can comprise metal, while the frame elements 110 comprise wood. This composite construction can be desirable to reduce production cost or increase rigidity while still enabling the frame elements 110 to be easily shaped and/or painted to match surrounding decor. In still other embodiments, the enclosure 115 and frame elements 110 may be integrally formed. In other words, in some embodiments, the top panel 125, side panels 150, and/or bottom panel 155 may be manufactured from a material that is sufficiently thick to allow the frame elements to be routed, or otherwise formed, therefrom. This can lower the number of pieces required to assemble the enclosure 115 and can reduce assembly costs, while still maintaining the aesthetics of the enclosure 115.

In some embodiments, the device 100 can further comprise power strips to enable the monitor 105 and/or other equipment to be conveniently powered and to minimize the number of power cords that must be run from the enclosure 115. In other contemplated embodiments, the enclosure 115 can further comprise internal brackets to facilitate the mounting of additional components such as, for example and not limitation, cable and satellite boxes, tuners, amplifiers, and video recorders. In still other embodiments, the enclosure 115 can further comprise internal brackets, or other means, to organize and store cords associated with the monitor 105 and/or other equipment.

In some embodiments, the device 100 can be custom manufactured to provide a precise fit for a specific monitor 105 and/or a specific mounting angle α. In other embodiments, the device 100 can be manufactured to fit, for example, specific, popular monitors 105 and/or monitors mounted at a set mounting angle α. This can enable the device 100, 200 to be mass produced and offered in a variety of popular monitor sizes and/or a variety of mounting angles to reduce cost while still providing functionality.

Numerous characteristics and advantages have been set forth in the foregoing description, together with details of structure and function. While the invention has been disclosed in several forms, it will be apparent to those skilled in the art that many modifications, additions, and deletions, especially in matters of shape, size, materials, and arrangement of parts, can be made therein without departing from the spirit and scope of the invention and its equivalents as set forth in the following claims. Therefore, other modifications or embodiments as may be suggested by the teachings herein are particularly reserved as they fall within the breadth and scope of the claims here appended.

What is claimed is:

1. A device for enclosing a wall-mounted flat panel monitor comprising:
a top panel, with a proximal end and a distal end, disposed in a substantially horizontal manner;
a first side panel disposed adjacent to the proximal end of the top panel with a trailing edge disposed in a substantially vertical manner and a leading edge disposed at substantially the same angle as a mounting angle for a flat panel monitor and such that the leading edge is longer than the trailing edge;
a second side panel disposed adjacent to the distal end of the top panel with a trailing edge disposed in a substantially vertical manner and a leading edge disposed at substantially the same angle as a mounting angle for a flat panel monitor and such that the leading edge is longer than the trailing edge.

2. The device of claim 1, the top panel further comprising one or more ventilation ports.

3. The device of claim 2, further comprising one or more cooling fans.

4. The device of claim 1, further comprising:
a bottom panel disposed adjacent to a bottom edge of the first and second side panels in a substantially horizontal manner.

5. The device of claim 1, further comprising one or more frame elements, disposed adjacent to a front face of one or more of the top panel, first side panel, second side panel, and bottom panel, for surrounding a flat panel monitor and defining an air gap therebetween.

6. The device of claim 4, further comprising a rear panel disposed adjacent to a rear edge of one or more of the top panel, side panels, and bottom panel.

7. The device of claim 5, the rear panel further comprising a rigid material for mounting a mounting bracket for a flat panel monitor.

8. The device of claim 5, the rear panel further comprising one or more mounting holes for mounting the device on a wall.

9. The device of claim 5, further comprising one or more mounting brackets disposed on a rear edge of one or more of the top panel, side panels, and bottom panel for attaching the device on a wall.

10. A device for enclosing a wall-mounted flat panel monitor comprising:
a top panel with a proximal end and a distal end and disposed in a substantially horizontal manner and further comprising a ventilation port;
a first side panel with an upper end disposed adjacent to the proximal end of the top panel, a trailing edge disposed in a substantially vertical manner, and a leading edge disposed at a positive angle to the trailing edge;
a second side panel, with an upper end disposed adjacent to the distal end of the top panel, a trailing edge disposed in a substantially vertical manner, and a leading edge disposed at a positive angle to the trailing edge;
a bottom panel disposed adjacent to a bottom end of the first side panel and the second side panel in a substantially horizontal manner; and
one or more frame elements, disposed adjacent to a front face of one or more of the top panel, first side panel, second side panels, and bottom panel, for surrounding a flat panel monitor and defining an air gap therebetween.

11. The device of claim 10, further comprising a cooling fan.

12. The device of claim 10, the leading edge of the first side panel and the second side panel disposed between approximately 5 degrees and 45 degrees and such that a top edge of the side panels is longer than a bottom edge of the side panels.

13. The device of claim 10, further comprising a rear panel detachably coupled to a rear edge of one or more of the top panel, side panels, and bottom panel.

14. The device of claim 13, the rear panel further comprising a rigid material for mounting a mounting bracket for a flat panel monitor thereon.

15. A method for manufacturing a device for enclosing a wall-mounted flat panel monitor comprising:
providing a top panel with a proximal end and a distal end;
providing a first side panel, comprising a proximal end and a distal end, and comprising a leading edge disposed at an angle that is substantially the same angle as a mounting angle for an enclosed flat panel monitor and non-vertical;
providing a second side panel comprising a proximal end and a distal end, and comprising a first edge disposed at an angle that is substantially the same angle as a mounting angle for an enclosed flat panel monitor and non-vertical;
providing a bottom panel;
providing one or more frame elements;
creating one or more ventilation ports in the top panel to provide airflow around a flat panel monitor;
attaching the proximal end of the first side panel to the proximal end of the top panel in a substantially perpendicular manner;
attaching the proximal end of the second side panel to the distal end of the top panel in a substantially perpendicular manner;
attaching the bottom panel to the distal end of the first side panel and second side panel; and
attaching one or more frame elements to a front edge of one or more of the top panel, bottom panel, and side panels for surrounding a flat panel monitor and defining an air gap therebetween.

16. The method of claim 15 further comprising:
providing one or more cooling fans; and
attaching the one or more cooling fans to a bottom side of the top panel such that they are substantially aligned with the one or more ventilations ports therein.

17. The method of claim 15, the top panel, side panels, and bottom panel comprising a single piece that is integrally formed.

18. The method of claim 15, the top panel, side panels, and bottom panel integrally formed with the one or more frame elements.

19. The method of claim 15, further comprising:
providing a rear panel; and
attaching the rear panel to a rear edge of one or more of the top panel, side panels, and bottom panel.

20. The method of claim 19, the rear panel comprising a rigid material for mounting a mounting bracket for a flat panel monitor thereon.
